(19) United States
(12) Patent Application Publication
(10) Pub. No.: US 2007/0018238 A1
(43) Pub. Date: Jan. 25, 2007

(54) Semiconductor device

(75) Inventor: Mizuki Ono, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/439,997

(22) Filed: May 25, 2006

(30) Foreign Application Priority Data
Jul. 6, 2005 (JP) 2005-197835

(51) Int. Cl. H01L 29/76

(52) U.S. Cl. 257/327

(57) ABSTRACT

A semiconductor device includes a semiconductor layer, a pair of a source region and a drain region formed to face each other in a direction on the semiconductor layer and made of a metal or a metal silicide, a first dielectric film formed on at least the semiconductor layer between the source region and the drain region, a second dielectric film formed on the first dielectric film and having a dielectric constant higher than that of the first dielectric film, and a gate electrode formed on the second dielectric film. A length of the second dielectric film measured in the direction is shorter than that of the gate electrode measured in the direction.

### CROSS-REFERENCE TO RELATED APPLICATIONS

This application is based upon and claims the benefit of priority from prior Japanese Patent Application No. 2005-197835, filed Jul. 6, 2005, the entire contents of which are incorporated herein by reference.

### BACKGROUND OF THE INVENTION

1. Field of the Invention

The present invention relates to a semiconductor device, more particularly to a Schottky-type field-effect transistor.

2. Description of the Related Art

To scale down a MOS-type field-effect transistor to several tens of nanometers, there are several problems to be solved. A first problem is a large tunnel current of a remarkably thin gate dielectric film, a second problem is diffusion of boron (B) which is an impurity element from a polysilicon gate electrode, and a third problem is formation of a remarkably shallow source/drain region having a low resistance.

It is considered that the first and second problems are solved by a metal gate electrode and a gate dielectric film having a high dielectric constant (high-k). As to the third problem, there is proposed a Schottky barrier silicide source/drain structure (see, e.g., Solid-State Electronics 48 [2004] 1987 to 1992). This structure is constituted using an interface between silicide and silicon, the interface being an atomic abrupt interface.

In the Schottky barrier silicide source/drain structure, it is demanded that a decrease in a current driving force is suppressed, the drop accompanying a variance of a relative positional relationship of a boundary between the source/drain region and a channel region with respect to the gate dielectric film, and that a high-performance fine semiconductor device capable of operating at a sufficiently high speed is realized.

### BRIEF SUMMARY OF THE INVENTION

According to a first aspect of the invention, there is provided a semiconductor device which comprises:

a semiconductor layer;

a pair of a source region and a drain region formed to face each other in a direction on the semiconductor layer and made of a metal or a metal silicide;

a first dielectric film formed on at least the semiconductor layer between the source region and the drain region;

a second dielectric film formed on the first dielectric film and having a dielectric constant higher than that of the first dielectric film; and

a gate electrode formed on the second dielectric film,

a length of the second dielectric film measured in the direction being shorter than that of the gate electrode measured in the direction.

According to a second aspect of the invention, there is provided a semiconductor device which comprises:

a semiconductor layer;

a pair of a source region and a drain region formed to face each other in a direction on the semiconductor layer and made of a metal or a metal silicide;

a first dielectric film formed on at least the semiconductor layer between the source region and the drain region;

a second dielectric film formed on the first dielectric film and having a dielectric constant higher than that of the first dielectric film; and

a gate electrode formed on the second dielectric film,

a length of the second dielectric film measured in the direction being shorter than that of the gate electrode measured in the direction, and the second dielectric film having a region whose opposing edges are aligned or overlap with the source region and the drain region.

According to a third aspect of the invention, there is provided a semiconductor device which comprises:

a semiconductor layer;

a pair of a source region and a drain region formed to face each other in a direction on the semiconductor layer and made of a metal or a metal silicide;

a first dielectric film formed on at least the semiconductor layer between the source region and the drain region;

a second dielectric film formed on the first dielectric film and having a dielectric constant higher than that of the first dielectric film; and

a gate electrode formed on the second dielectric film,

a length of the second dielectric film measured in the direction being shorter than that of the gate electrode measured in the direction, the gate electrode having a region which overlaps with at least a part of the source region and the drain region, and the overlapping region having a void.

### BRIEF DESCRIPTION OF THE SEVERAL VIEWS OF THE DRAWING

FIG. 1 is a sectional view of a conventional Schottky-type field-effect transistor;

FIG. 2 is a characteristic diagram showing a problem of a field-effect transistor, which is to be solved by the present invention;

FIG. 3 is a sectional view of a field-effect transistor, showing a case where there is an offset between opposing edges of a gate dielectric film and a source/drain region;

FIG. 4 is a sectional view showing that the source/drain region overlaps with the gate dielectric film;

FIG. 5 is a characteristic diagram showing a relationship between a relative position of opposing edges of a source/drain region with respect to a gate dielectric film and a drain current;

FIG. 6 is a sectional view showing a constitution of a semiconductor device of the present invention;

FIG. 7 is a characteristic diagram showing a relationship between a relative position of opposing edges of a source/drain region with respect to a gate dielectric film and a drain current in the present invention;

FIG. 8 is another characteristic diagram showing the relationship between a relative position of the opposing edges of the source/drain region with respect to the gate dielectric film and the drain current in the present invention;

FIG. 9 is still another characteristic diagram showing the relationship between a relative position of the opposing edges of the source/drain region with respect to the gate dielectric film and the drain current in the present invention;

FIG. 10 is a sectional view showing a structure of a field-effect transistor in a first embodiment of the present invention;

FIGS. 11 to 15 are sectional views showing a process of manufacturing the field-effect transistor in a stepwise manner in the first embodiment of the present invention;

FIG. 16 is a sectional view showing a structure of a field-effect transistor in a second embodiment of the present invention;

FIGS. 17 to 22 are sectional views showing a process of manufacturing the field-effect transistor in a stepwise manner in the second embodiment of the present invention;

FIG. 23 is a sectional view showing a structure of a field-effect transistor in a third embodiment of the present invention; and

FIG. 24 is a sectional view showing a process of manufacturing the field-effect transistor in the third embodiment of the present invention.

### DETAILED DESCRIPTION OF THE INVENTION

The present invention will be generally described prior to description of embodiments. First, there will be described problems of the above-described Schottky-type field-effect transistor based on the present inventor's findings. FIG. 1 shows a typical sectional view of a generally known Schottky-type field-effect transistor. Here, there will be described an N-channel field-effect transistor as an example. As shown in FIG. 1, in a conventional field-effect transistor, an isolation region 2 is formed on a semiconductor substrate 1 by a trench isolation process. In the semiconductor substrate 1, an N-channel region 3 is formed by boron (B) ion implantation. On the N-channel region 3, a gate dielectric film 4 is formed by a dielectric film of metal oxide or the like having a dielectric constant which is higher than that of silicon oxide. A refractory metal having a thickness of 100 nm is deposited on the gate dielectric film 4 by a sputtering process to form a gate electrode 5. A silicide layer is formed so that source/drain regions 6 are formed to sandwich the gate electrode 5 therebetween. The gate electrode is usually formed to overlap with edges of the source and drain regions in order to secure a current driving force. It is to be noted that in this drawing, an interlayer dielectric film, interconnections and the like are omitted.

In the above-described conventional field-effect transistor, the gate electrode is made of a refractory metal having a low resistance for a purpose of increasing an operation speed of the device. Furthermore, the gate dielectric film is formed of a material whose dielectric constant is higher than that of silicon oxide, that is, a high-dielectric-constant material such as metal oxide in order to increase a current driving force, improve controllability of the gate electrode with respect to a potential of a channel region, and suppress a gate current, when the film is formed to be thick.

A strength of capacitive coupling between the channel region and a gate electrode is determined by “equivalent oxide thickness (EOT)” obtained by dividing, by the dielectric constant of the dielectric film, a product of a film thickness of the dielectric film in a geometric sense and a dielectric constant (3.9) of silicon oxide. Therefore, when the dielectric film is formed of the high-dielectric-constant material, it is possible to form the gate dielectric film to be thick while keeping controllability of the gate electrode with respect to the potential of the channel region. Therefore, it is possible to suppress the gate current while keeping controllability of the gate electrode with respect to the potential of the channel region.

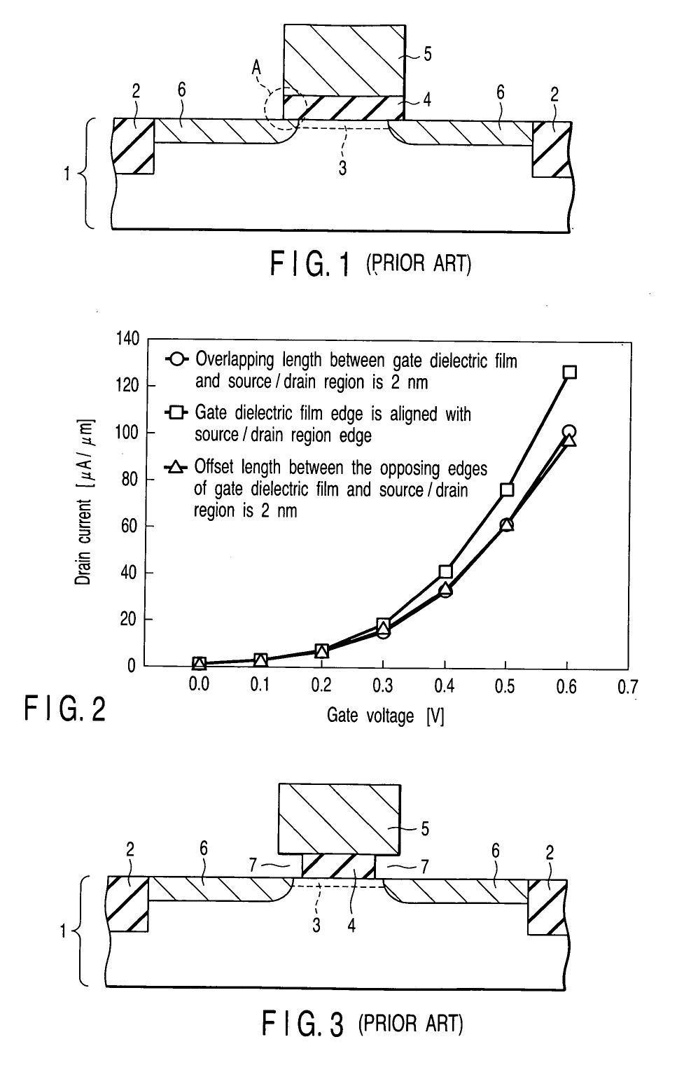

In addition, FIG. 2 shows a simulation result of dependency of a drain current on a gate voltage in a case where there is used, in the gate dielectric film, a high-dielectric-constant other than conventional silicon oxide. It is seen from FIG. 2 that if a boundary between the source/drain region and the channel region is aligned with a gate dielectric film edge (as shown by squares in FIG. 2), the largest drain current is obtained. However, it is seen that in a case where both of the boundary and the edge are not aligned with each other, even when they overlap with each other (as shown by circles in FIG. 2) or there is an offset between them (as shown by triangles in FIG. 2), a decrease of a current value is caused. Therefore, there is a demand for subtle adjustment of a positional relationship between them. This inhibits the current driving force from being raised.

It is to be noted that an element for use in this simulation is made of a metal having a channel length of 35 nm, an overlapping length of 3 nm between the source/drain region and the gate region, an equivalent oxide thickness of 1 nm of the gate dielectric film, and a source/drain junction depth of 10 nm. FIG. 2 shows a value per unit width (1 μm) of the drain current in a drain voltage (V_{D})=0.6 V. It is to be noted that the source voltage (V_{S})=a substrate voltage (V_{SUB})=0 V. It is also assumed that the dielectric constant of the gate dielectric film is 19.5 (five times the dielectric constant of heretofore used silicon oxide).

The current driving force is influenced by a relative positional relationship of the boundary between the source/drain region and the channel region with respect to the edge of the gate dielectric film for the following reasons. First, there is supposed a case where there is the offset between the opposing edges of the source/drain region and the gate dielectric film. In this case, as shown in a schematic sectional view of FIG. 3, between the gate dielectric film and the source/drain regions, a region 7 between the gate electrode and the semiconductor substrate is filled with a material whose dielectric constant is smaller than that of the gate dielectric film, such as the interlayer dielectric film or a gate sidewall (not shown). This equivalently means that the gate dielectric film of this region only is formed of a material having a small dielectric constant. That is, in this region only, the controllability of the gate electrode is low as compared with another region of a channel. As a result, in a state in which the element turns on, that is, in a case where a positive potential is applied to a gate in an n-type field-effect transistor, and a negative potential is applied to a p-type field-effect transistor, a resistance of the region is high as compared with another region of the channel. As a result, a resistance increases, and the current driving force decreases in the on-state of the element. This is because the current driving force drops in a case where there is the offset between the opposing edges of the source/drain region and the gate dielectric film as shown in FIG. 2.

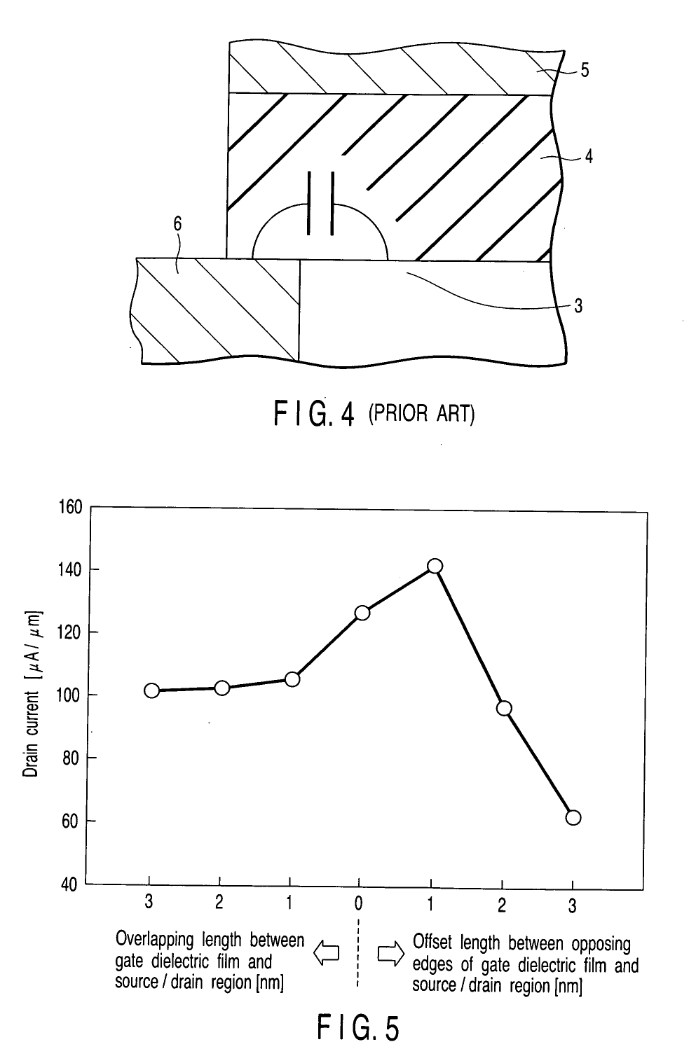

Next, there is considered a case where the source/drain region overlaps with the gate dielectric film. FIG. 4 is a schematic enlarged view of a portion corresponding to A of FIG. 1. As shown in FIG. 4, in this case, the capacitive coupling is formed between the source region 6 and the channel region 3 by a line of electric force extending through the gate dielectric film 4. In a case where the high-dielectric-constant material is used in the gate dielectric film, the dielectric constant of the dielectric film is high, and the film thickness of the gate dielectric film is large in the geometric sense as described above as compared with a case where conventional silicon oxide is used in the gate dielectric film. Therefore, the capacitive coupling formed between the source region 6 and the channel region 3 is strong. As a result, the potential of the channel region 3 is brought close to that of the source region 6. Accordingly, the Schottky barrier formed between the source region 6 and the channel region 3 is thick, and this decreases a probability that a carrier passes through the barrier owing to a tunnel effect. That is, the resistance of the region increases. As a result, the current driving force drops. This is because the current driving force drops in a case where the source/drain region overlaps with the edge of the gate dielectric film as shown in FIG. 2.

Therefore, to obtain a large current driving force in the Schottky-type field-effect transistor, there is a demand for the subtle adjustment of the relative positional relationship of the boundary between the source/drain region and the channel region with respect to the edge of the gate dielectric film. As described in accordance with this example, the source/drain region usually overlaps with the gate electrode. Therefore, to realize the largest current driving force, the gate dielectric film needs to be formed to be shorter than the gate electrode. FIG. 5 shows a simulation result of the drain current in a case where the relative positional relationship of the boundary between the source/drain region and the channel region with respect to the edge of the gate dielectric film is changed.

A device used in this simulation has a channel length of 35 nm, an overlapping length of 3 nm between the source/drain region and the gate region, an equivalent oxide thickness of 1 nm of the gate dielectric film, and a source/drain junction depth of 10 nm. FIG. 5 shows a value per unit width (1 μm) of the drain current in a drain voltage (V_{D})=a gate voltage (V_{G})=0.6 V. It is to be noted that the source voltage (V_{S})=the substrate voltage (V_{SUB})=0 V. It is also assumed that the dielectric constant of the gate dielectric film is 19.5 (five times the dielectric constant of the generally used silicon oxide).

In FIG. 5, the ordinate shows the drain current, and the abscissa shows the relative positional relationship of the boundary between the source/drain region and the channel region with respect to the edge of the gate dielectric film. The value indicates an offset length in a case where there is an offset between the boundary and the edge on the right side of a value of zero of the abscissa. The value indicates an overlapping length in a case where the boundary overlaps with the edge on the left side of the value of zero. In FIG. 5, in antagonism between two reasons described above, the current is maximized in a case where there is an offset of 1 nm, that is, each of opposite edges of the gate dielectric film is recessed from the gate electrode as much as 4 nm. If the positional relationship between them deviates from this state as much as only 1 nm, the current abruptly decreases.

To obtain the high current driving force in the Schottky-type field-effect transistor in this manner, there is a demand for subtle adjustment of the relative positional relationship of the boundary between the source/drain region and the channel region with respect to the edge of the gate dielectric film. Even when the positional relationship between them is designated so that the current driving force is maximized, a fluctuation is generated in the positional relationship owing to the fluctuation of a manufacturing process. It is remarkably difficult to suppress the fluctuation of the manufacturing process to several atoms, typically about 1 nm or less. This causes an abrupt decrease of the current driving force as shown in FIG. 5. Therefore, an average value of the current driving force of the device largely decreases, and this eventually obstructs the increase of the current driving force.

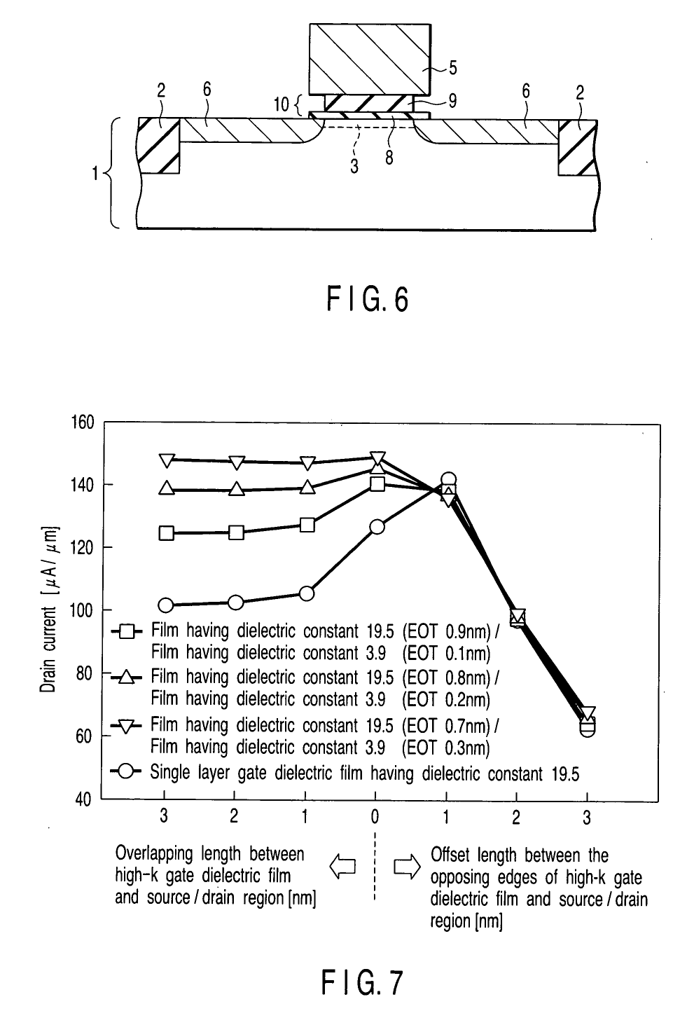

FIG. 6 is a sectional view showing a schematic structure of a field-effect transistor of the present invention. In the field-effect transistor of the present invention, a gate dielectric film 10 is constituted of a laminated film including a semiconductor-substrate-side dielectric film 8 having a low dielectric constant, and a gate-electrode-side dielectric film 9 having a high dielectric constant. The transistor is equivalent to the element (i.e., FIG. 3) whose simulation result is shown in FIG. 5 except the structure of the gate dielectric film.

FIG. 7 shows a simulation result of the value per unit width (1 μm) of the drain current at the drain voltage (V_{D})=the gate voltage (V_{G})=0.6 V with respect to the device shown in FIG. 6. It is to be noted that the source voltage (V_{S})=the substrate voltage (V_{SUB})=0 V. An overlapping length between the source/drain region and the gate electrode is 3 nm.

In FIG. 7, the ordinate indicates the drain current, and the abscissa indicates a relative positional relationship of the boundary between the source/drain region and the channel region with respect to the edge of the high-dielectric-constant (high-k) gate dielectric film. The value indicates an offset length in a case where there is an offset between the boundary and the edge on the right side of a value of zero of the abscissa. The value indicates an overlapping length in a case where the boundary overlaps with the edge on the left side of the value of zero.

Moreover, in FIG. 7, circles indicate a single layer gate dielectric film having a dielectric constant of 19.5 (the same film as that shown in FIG. 5), and squares indicate a laminated gate dielectric film including a film having a dielectric constant=19.5 (EOT=0.9 nm) on the gate electrode side, and a film having a dielectric constant=3.9 (EOT=0.1 nm) on the semiconductor substrate side. Moreover, triangles indicate a laminated gate dielectric film including a film having a dielectric constant=19.5 (EOT=0.8 nm) on the gate electrode side, and a film having a dielectric constant=3.9 (EOT=0.2 nm) on the semiconductor substrate side, and inverted triangles indicate a laminated gate dielectric film including a film having a dielectric constant=19.5 (EOT=0.7 nm) on the gate electrode side, and a film having a dielectric constant=3.9 (EOT=0.3 nm) on the semiconductor substrate side.

In this simulation, the edge of the film disposed on the semiconductor substrate side and having a dielectric constant=3.9 is worked to be aligned with the gate electrode. Here, calculation is performed assuming that the interlayer dielectric film surrounding a periphery of the gate electrode has a dielectric constant=3.9. Hence, even if the edge of the film disposed on the semiconductor substrate side and having a dielectric constant=3.9 is disposed in any portion, the result shown in FIG. 7 is not influenced.

As seen from FIG. 7, in a case where the gate dielectric film is a laminated film having a low dielectric constant on the semiconductor substrate side and a high dielectric constant on the gate electrode side, a fluctuation of the drain current value is remarkably effectively suppressed, the fluctuation being generated at a time when changing the relative positional relationship of the boundary between the source/drain region and the channel region with respect to the edge of the high-dielectric-constant (high-k) film (this may be replaced with the edges of the gate dielectric film, because the result is not influenced by the position of the edge of a low-dielectric-constant film on the semiconductor substrate side for the above-described reason), as compared with the case where the gate dielectric film has a single layer structure (shown by circles in FIG. 7) of the high-dielectric-constant film. It is especially noteworthy that the effect more largely appears in a case where the overlapping length between the high-dielectric- constant (high-k) gate dielectric film and the source/drain region is small, that is, each edge of the high-dielectric-constant dielectric film is recessed from the gate electrode.

The reason is as follows. In the structure whose section is schematically shown in FIG. 6, a region of the gate dielectric film formed of a material having a high dielectric constant is distant from the semiconductor substrate. This suppresses an influence, on the drain current, the relative positional relationship of the boundary between the source/drain region and the channel region with respect to the edge of the film formed of the high-dielectric-constant material. This is a newly obtained finding in the present investigation.

Moreover, referring to FIG. 7, the current driving force is remarkably improved at a time when the source/drain region overlaps with the high-dielectric-constant gate dielectric film in a case where the gate dielectric film is constituted of laminated layers as compared with a case where the gate dielectric film is a single layer film of the high-dielectric-constant material. The reason is as follows.

In the structure of FIG. 6, the gate dielectric film on the semiconductor substrate side is formed of a low-dielectric-constant material. Therefore, the capacitive coupling weakens as compared with a case where the gate dielectric film is a single layer film formed of the high-dielectric-constant material. The capacitive coupling is formed between the source region and the channel region depending on the electric force line extending through the gate dielectric film, and the capacitive coupling is a reason why the current driving force drops in a case where the source/drain region overlaps with the gate dielectric film in the conventional element. In consequence, in a case where the source/drain region overlaps with the high-dielectric-constant gate dielectric film, the current driving force is largely improved as compared with the gate dielectric film is a single layer film of the high-dielectric-constant material.

As a result, in the gate dielectric film constituted of the laminated film, especially in a case where the source/drain region overlaps with the layer of the gate dielectric film, which is formed of the high-dielectric-constant material, there is suppressed dependence of the drain current value on the relative position of the boundary between the source/drain region and the channel region with respect to the edge of the high-dielectric-constant gate dielectric film. Therefore, the edge of the source/drain region is preferably aligned or overlaps with the edge of the high-dielectric-constant material layer of the gate dielectric film. This is also a new finding obtained in the present investigation.

When the gate dielectric film is constituted of the laminated dielectric film formed of the high-dielectric-constant material on the gate electrode side and the low-dielectric-constant material on the semiconductor substrate side in this manner, as described above in the related art, there is an advantage that the gate current can be suppressed while keeping controllability of the gate electrode with respect to the potential of the channel region. There is another advantage that it is possible to suppress the capacitive coupling between the source region and the channel region depending on the electric force lines extending through the gate dielectric film as shown in FIG. 7. To effectively realize the latter advantage, the layer of the gate dielectric film close to the semiconductor substrate is preferably formed of the low-dielectric-constant material. Therefore, when this layer close to the semiconductor substrate is formed of silicon oxide (dielectric constant=3.9), the effect of the present invention is especially effectively obtained.

Moreover, in a case where the layer of the gate dielectric film which comes into contact with the semiconductor substrate is made of silicon oxide, an interfacial state formed in the interface between the layer and the semiconductor substrate is reduced. As a result, there is also obtained an advantage that a carrier is inhibited from being scattered by a electric charge existing in the state to improve a mobility of the carrier, and a large current driving force is obtained.

Referring to FIG. 7, when the silicon oxide layer formed on the semiconductor substrate side has a thickness of 0.2 nm or more, a large drain current is obtained as compared with a case where the gate dielectric film is a single layer film having a dielectric constant=19.5 and the edge of the source/drain region is aligned with that of the high-dielectric-constant gate dielectric film (i.e., the abscissa indicates 0). Furthermore, it is seen that in a case where the thickness of the silicon oxide layer is 0.3 nm or more, the drain current is obtained which is larger than the largest drain current obtained in a case where the gate dielectric film is a single layer film having a dielectric constant=19.5.

Therefore, in a case where the layer of the gate dielectric film close to the semiconductor substrate is made of silicon oxide, the thickness of the layer is preferably 0.2 nm or more, more preferably 0.3 nm or more. On the other hand, a reason why the high-dielectric-constant material is used in the gate dielectric film is that the gate current is suppressed by increasing the film thickness of the gate dielectric film in the geometric sense. Therefore, if the layer close to the semiconductor substrate is formed to be excessively thick, there arises a need of forming the gate dielectric film on the gate electrode side to be thin in order to keep a total equivalent oxide thickness of the gate dielectric film to be small for a purpose of keeping the controllability of the gate electrode with respect to the potential of the channel region. This unfavorably causes an increase of the gate current. Therefore, the equivalent oxide thickness of the layer close to the semiconductor substrate is preferably reduced to about half of the total equivalent oxide thickness of the gate dielectric film. In the example described herein, the total equivalent oxide thickness of the gate dielectric film is set to 1 nm. Therefore, the equivalent oxide thickness of the layer close to the semiconductor substrate is preferably about 0.5 nm or less.

Moreover, when the gate dielectric film is a laminated dielectric film formed of the high-dielectric-constant material on the gate electrode side and the low-dielectric-constant material on the semiconductor substrate side, the current driving force is improved especially in a case where the boundary between the source/drain region and the channel region overlaps with the high-dielectric-constant gate dielectric film. This suppresses dependency of the drain current with respect to the positions of the boundary between the source/drain region and the channel region and the edge of the high-dielectric-constant gate dielectric film.

That is, it is seen that in a case where the gate dielectric film is a laminated dielectric film formed of the high-dielectric-constant material on the gate electrode side and the low-dielectric-constant material on the semiconductor substrate side, when the source/drain region does not overlap with the gate dielectric film, the current driving force drops. However, when the source/drain region overlaps with the gate dielectric film, the influence of the overlapping length on the drain current is remarkably small. As seen from FIG. 7, a high drain current is obtained in a case where the offset length between the opposing edges of the source/drain region and the high-dielectric-constant gate dielectric film is up to 1 nm. However, in consideration of safety, the opposing edges of the source/drain region and the high-dielectric-constant gate dielectric film may be aligned or overlap with each other.

Therefore, it is important for the current driving force that the high-dielectric-constant material overlaps with the source/drain region, but the overlapping length is not essential. On the other hand, in view of a parasitic capacitance of the element, the overlapping of the high-dielectric-constant material with the source/drain region unfavorably results in an increase of the parasitic capacitance. In view of this, a region other than a region including the gate dielectric film formed of the high-dielectric-constant material is preferably formed of a low-dielectric-constant material in the overlapping region of the source/drain region with the gate electrode. If there is a void, the dielectric constant unfavorably remarkably drops. Therefore, the high-dielectric-constant gate dielectric film is preferably recessed (retreated) from the gate electrode edge.

It is to be noted that the present invention suppresses the drop of the current driving force attributable to the capacitive coupling formed between the source region and the channel region by the electric force line extending through the gate dielectric film, which appears in the structure of the conventional technology. Therefore, the effect is remarkable especially in a case where the dielectric constant is high as in a case where the layer of the gate dielectric film formed of the high-dielectric-constant material is formed of a material including a metal such as hafnium (Hf), zirconium (Zr), titanium (Ti), scandium (Sc), yttrium (Y), tantalum (Ta), aluminum (Al), lanthanum (La), cerium (Ce), praseodymium (Pr), or a lanthanum series element.

There has been described above a case where the layer of the gate dielectric film close to the semiconductor substrate is made of silicon oxide. If a nitrogen-containing material such as silicon nitride or silicon oxynitride is used in this layer, there is obtained an advantage that impurities in the gate electrode are inhibited from being diffused in the channel region in a case where an impurities-containing semiconductor is used in the gate electrode. Moreover, reliability of the gate dielectric film is improved. The dielectric constant of silicon nitride is 7.8, and the dielectric constant of silicon oxynitride is between 7.8 and a value (3.9) of silicon oxide.

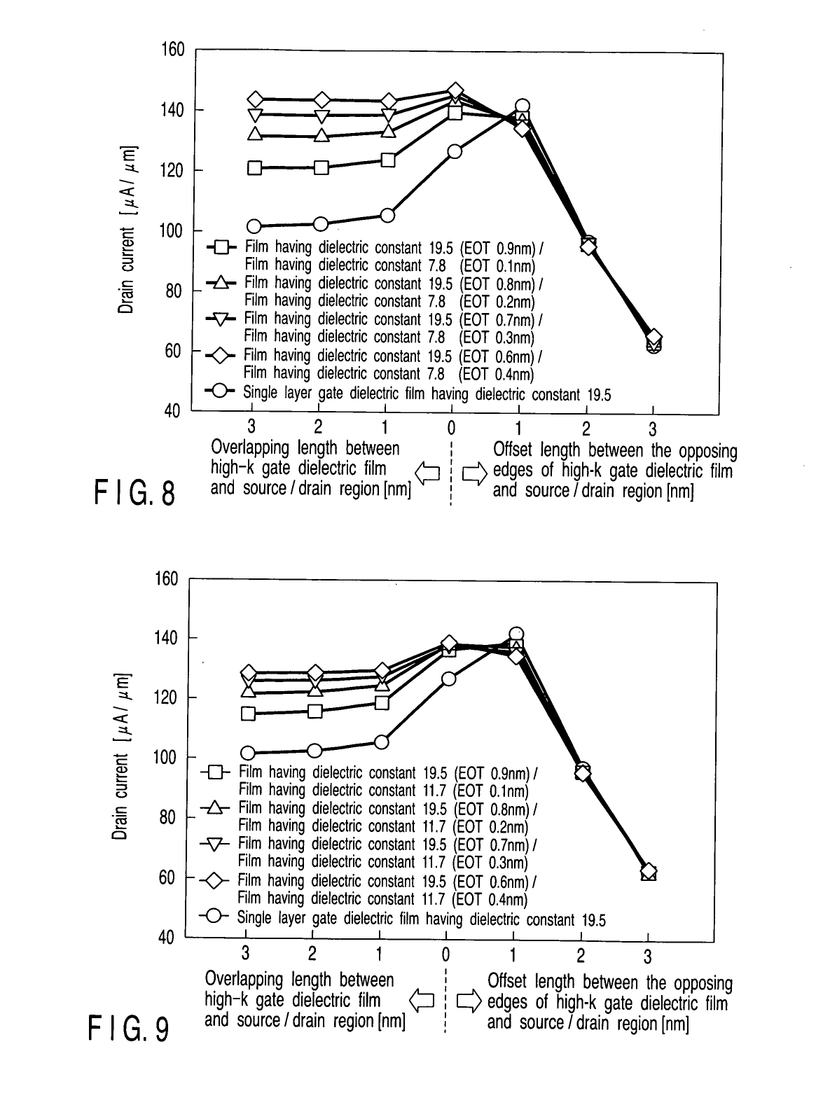

FIG. 8 shows a result of a case where investigation equivalent to that of FIG. 7 is performed at a time when the dielectric constant of the layer of the gate dielectric film close to the semiconductor substrate is set to 7.8. The ordinate indicates a drain current, and the abscissa indicates a relative positional relationship of the boundary between the source/drain region and the channel region with respect to the edge of the high-dielectric-constant gate dielectric film. The value indicates an offset length in a case where there is an offset between the boundary and the edge on the right side of a value of zero of the abscissa. The value indicates an overlapping length in a case where the boundary overlaps with the edge on the left side of the value of zero.

Furthermore, in FIG. 8, circles indicate a single layer gate dielectric film having a dielectric constant of 19.5 (the same film as that shown in FIG. 5), and squares indicate a laminated gate dielectric film including a film having a dielectric constant=19.5 (EOT=0.9 nm) on the gate electrode side, and a film having a dielectric constant=7.8 (EOT=0.1 nm) on the semiconductor substrate side. Moreover, triangles indicate a laminated gate dielectric film including a film having a dielectric constant=19.5 (EOT=0.8 nm) on the gate electrode side, and a film having a dielectric constant=7.8 (EOT=0.2 nm) on the semiconductor substrate side, and inverted triangles indicate a laminated gate dielectric film including a film having a dielectric constant=19.5 (EOT=0.7 nm) on the gate electrode side, and a film having a dielectric constant=7.8 (EOT=0.3 nm) on the semiconductor substrate side. Furthermore, rhombuses indicate a laminated gate dielectric film including a film having a dielectric constant=19.5 (EOT=0.6 nm) on the gate electrode side, and a film having a dielectric constant=7.8 (EOT=0.4 nm) on the semiconductor substrate side.

In this simulation, it is assumed that the edge of the film disposed on the semiconductor substrate side and having a dielectric constant=7.8 is worked to be aligned with the edge of the film disposed on the gate electrode side and having a dielectric constant=19.5, but the similar result is intrinsically obtained even if the edge of the film is aligned with the edge of the gate electrode in the same manner as in a sectional structure schematically shown in FIG. 6. As seen from FIG. 8, a fluctuation of the drain current is remarkably effectively suppressed, the fluctuation being generated at a time when changing the relative positional relationship of the boundary between the source/drain region and the channel region with respect to the edge of the high-dielectric-constant film (this may be replaced with the edges of the gate dielectric film for the above-described reason) as compared with the case where the gate dielectric film has a single layer structure (shown by circles in FIG. 8) of the high-dielectric-constant film in the same manner as in FIG. 7. It is especially noteworthy that the effect more largely appears in a case where the overlapping length between the high-dielectric-constant gate dielectric film and the source/drain region is small, that is, each edge of the high-dielectric-constant dielectric film is recessed from the gate electrode.

Moreover, it is also seen that in a case where the gate dielectric film is constituted of laminated layers, the current driving force is remarkably improved especially at a time when the source/drain region overlaps with the high-dielectric-constant gate dielectric film as compared with a case where the gate dielectric film is a single layer film of the high-dielectric-constant material. This is also a finding newly obtained in the present investigation. As seen from FIG. 8, a high drain current is obtained in a case where the offset length between the opposing edges of the source/drain region and the high-dielectric-constant gate dielectric film is up to 1 nm. However, in consideration of the safety, the opposing edges of the source/drain region and the high-dielectric-constant gate dielectric film may be aligned or overlap with each other.

As seen from FIG. 8, when the low-dielectric-constant layer formed on the side of the semiconductor substrate has an equivalent oxide thickness of 0.2 nm or more, a large drain current is obtained as compared with a case where the gate dielectric film is a single layer film having a dielectric constant=19.5 and the boundary between the source/drain region and the channel region is aligned with the edge of the high-dielectric-constant gate dielectric film. Furthermore, when the equivalent oxide thickness of the low-dielectric-constant layer is 0.4 nm or more, the drain current is obtained which is larger than the largest drain current obtained in a case where the gate dielectric film is a single layer film having a dielectric constant=19.5.

Therefore, in a case where the layer of the gate dielectric film close to the semiconductor substrate is made of silicon nitride or silicon oxynitride, the equivalent oxide thickness of the layer is preferably 0.2 nm or more, more preferably 0.4 nm or more.

On the other hand, a reason why the high-dielectric-constant material is used in the gate dielectric film is that the gate current is suppressed by increasing the film thickness of the gate dielectric film in the geometric sense. Therefore, if the layer close to the semiconductor substrate is formed to be excessively thick, there arises a need of setting the whole film thickness of the gate dielectric film in the geometric sense to be small in order to keep the total equivalent oxide thickness of the gate dielectric film to be small for a purpose of keeping the controllability of the gate electrode with respect to the potential of the channel region. This unfavorably causes an increase of the gate current. Therefore, the equivalent oxide thickness of the layer close to the semiconductor substrate is preferably reduced to about half of the total equivalent oxide thickness of the gate dielectric film. In the example described herein, the total equivalent oxide thickness of the gate dielectric film is set to 1 nm. Therefore, the equivalent oxide thickness of the layer close to the semiconductor substrate is preferably about 0.5 nm or less.

There has been described above a case where the layer of the gate dielectric film close to the semiconductor substrate is made of silicon oxide, silicon nitride, or silicon oxynitride. However, when there is used, in this layer, a material containing a metal, silicon, and oxygen, such as metal silicate, there is obtained an advantage that an equivalent oxide thickness is realized which is equal to that in a case where there is used, in this layer, silicon oxide, silicon nitride, or silicon oxynitride, it is possible to increase the film thickness in the geometric sense, and as a result, the gate current is suppressed. In general, a dielectric constant of the metal silicate material depends on a type or a composition of an element, but the dielectric constant is typically about 12.

FIG. 9 shows a result of a case where the investigation equivalent to that of FIG. 7 is performed at a time when the dielectric constant of the layer of the gate dielectric film close to the semiconductor substrate is set to 11.7. The ordinate indicates a drain current, and the abscissa indicates a relative positional relationship of the boundary between the source/drain region and the channel region with respect to the edge of the high-dielectric-constant gate dielectric film. The value indicates an offset length in a case where there is an offset between the boundary and the edge on the right side of a value of zero of the abscissa. The value indicates an overlapping length in a case where the boundary overlaps with the edge on the left side of the value of zero.

Furthermore, in FIG. 9, circles indicate a single layer gate dielectric film having a dielectric constant of 19.5 (the same film as that shown in FIG. 5), and squares indicate a laminated gate dielectric film including a film having a dielectric constant=19.5 (EOT=0.9 nm) on the gate electrode side, and a film having a dielectric constant=11.7 (EOT=0.1 nm) on the semiconductor substrate side. Moreover, triangles indicate a laminated gate dielectric film including a film having a dielectric constant=19.5 (EOT=0.8 nm) on the gate electrode side, and a film having a dielectric constant=11.7 (EOT=0.2 nm) on the semiconductor substrate side, and inverted triangles indicate a laminated gate dielectric film including a film having a dielectric constant=19.5 (EOT=0.7 nm) on the gate electrode side, and a film having a dielectric constant=11.7 (EOT=0.3 nm) on the semiconductor substrate side. Furthermore, rhombuses indicate a laminated gate dielectric film including a film having a dielectric constant=19.5 (EOT=0.6 nm) on the gate electrode side, and a film having a dielectric constant=11.7 (EOT=0.4 nm) on the semiconductor substrate side.

In this simulation, it is assumed that the edge of the film disposed on the semiconductor substrate side and having a dielectric constant=11.7 is worked to be aligned with the edge of the film disposed on the gate electrode side and having a dielectric constant=19.5, but the similar result is intrinsically obtained even if the edge of the film is aligned with the edge of the gate electrode in the same manner as in the structure schematically shown in FIG. 6.

As seen from FIG. 9, a fluctuation of the drain current is remarkably effectively suppressed, the fluctuation being generated at a time when changing the relative positional relationship of the boundary between the source/drain region and the channel region with respect to the edge of the high-dielectric-constant film (this may be replaced with the edges of the gate dielectric film for the above-described reason) as compared with the case where the gate dielectric film has a single layer structure (shown by circles in FIG. 9) of the high-dielectric-constant film in the same manner as in FIG. 7. It is especially noteworthy that the effect more largely appears in a case where the overlapping length between the high-dielectric-constant gate dielectric film and the source/drain region is small, that is, each edge of the high-dielectric-constant dielectric film is recessed from the gate electrode.

Moreover, it is also seen that the current driving force is remarkably improved especially at a time when the source/drain region overlaps with the high-dielectric-constant gate dielectric film in a case where the gate dielectric film is constituted of laminated layers as compared with a case where the gate dielectric film is a single layer film of the high-dielectric-constant material. This is a finding newly obtained in the present investigation. As seen from FIG. 9, a high drain current is obtained in a case where the offset length between the opposing edges of the source/drain region and the high-dielectric-constant gate dielectric film is up to 1 nm. However, in consideration of the safety, the opposing edges of the source/drain region and the high-dielectric-constant gate dielectric film may be aligned or overlap with each other.

As seen from FIG. 9, when the low-dielectric-constant layer formed on the semiconductor substrate side has an equivalent oxide thickness of 0.4 nm or more, a large drain current is obtained as compared with a case where the gate dielectric film is a single layer film having a dielectric constant=19.5 and the boundary between the source/drain region and the channel region is aligned with the edge of the high-dielectric-constant gate dielectric film. Therefore, when the layer of the gate dielectric film close to the semiconductor substrate is formed of a material including a metal, silicon, and oxygen, the equivalent oxide thickness is preferably 0.4 nm or more.

On the other hand, a reason why the high-dielectric-constant material is used in the gate dielectric film is that the gate current is suppressed by increasing the film thickness of the gate dielectric film in the geometric sense. Therefore, if the layer close to the semiconductor substrate is formed to be excessively thick, there arises a need of setting the whole film thickness of the gate dielectric film in the geometric sense to be small in order to keep the total equivalent oxide thickness of the gate dielectric film to be small for a purpose of keeping the controllability of the gate electrode with respect to the potential of the channel region. This unfavorably causes an increase of the gate current. Therefore, the equivalent oxide thickness of the layer close to the semiconductor substrate is preferably reduced to about half of the total equivalent oxide thickness of the gate dielectric film. In the example described herein, the total equivalent oxide thickness of the gate dielectric film is set to 1 nm. Therefore, the equivalent oxide thickness of the layer close to the semiconductor substrate is preferably about 0.5 nm or less.

A semiconductor device of an embodiment of the present invention described hereinafter is a Schottky-type field-effect transistor, a gate dielectric film is a laminated dielectric film having a high dielectric constant on a side close to a gate electrode and a low dielectric constant on a side close to the substrate. A length of at least a layer having a high dielectric constant in a direction in which the source region faces the drain region (hereinafter, referred as “a (the) direction”) is formed to be shorter than that of the gate electrode in the direction.

As a result, it is possible to set the thickness of the gate dielectric film in the geometric sense to be large as compared with the gate dielectric film is formed of conventional silicon oxide only. Therefore, it is possible to suppress a current flowing through the gate dielectric film while keeping the controllability of the gate electrode with respect to the potential of the channel region.

On the other hand, the film formed of the high-dielectric-constant material is formed to be distant from the semiconductor substrate as compared with a case where the gate dielectric film is formed of the high-dielectric-constant material only. This suppresses an influence on the current driving force by the relative positions of the boundary between the source/drain region and the channel region and the edge of the film formed of the high-dielectric-constant material. In consequence, a fluctuation of the current driving force attributable to a working fluctuation is suppressed. As a result, there is realized a high-performance fine semiconductor device capable of operating at a high speed.

Embodiments of the present invention will be described hereinafter in detail in accordance with typical examples. The present invention is not limited to the following embodiments, and can be variously modified for use.

(First Embodiment)

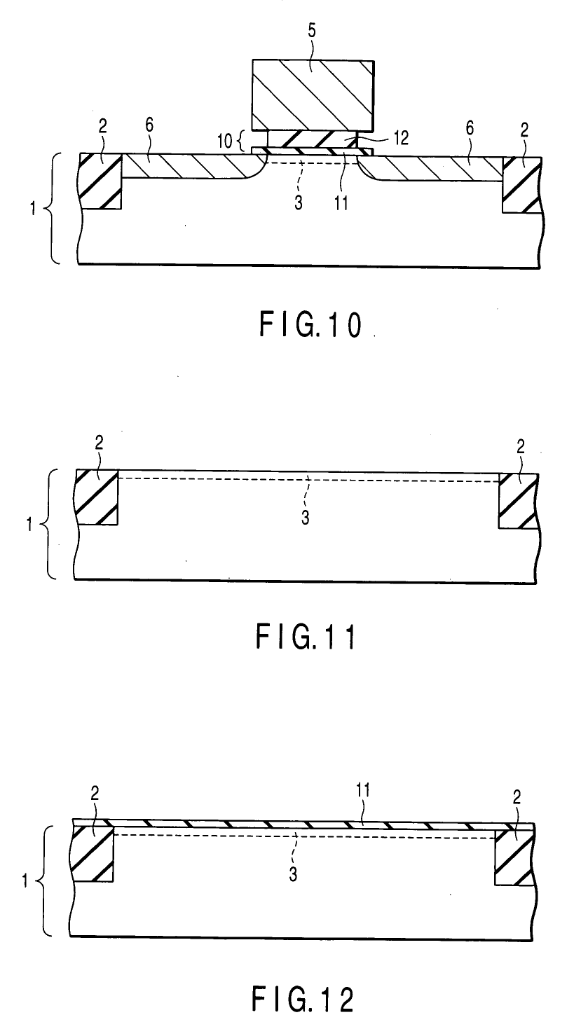

FIG. 10 shows a sectional view of a field-effect transistor in a first embodiment. In the present embodiment, an N-channel field-effect transistor will be described as an example. If a conductivity type of impurities is reversed, the present embodiment is applicable even to a P-channel field-effect transistor in the same manner. When using a process of injecting the impurities into an only specific region of a substrate by use of a process such as photolithography, the present embodiment is also applicable to a complementary field-effect transistor, and the similar effect is obtained.

This field-effect transistor is a Schottky-type field-effect transistor. Characteristics are that a gate dielectric film 10 is a laminated film including a film 11 made of silicon oxide and a film 12 formed of a high-dielectric-constant material such as metal oxide and that the film formed of the high-dielectric-constant material is recessed from the gate electrode. In this case, it is possible to increase a film thickness of the gate dielectric film in a geometric sense as compared with a case where a gate dielectric film having an equal equivalent oxide thickness is entirely made of conventional silicon oxide. Therefore, a current flowing through the gate dielectric film is suppressed.

Moreover, in this case, the layer formed of the high-dielectric-constant material is detached from the semiconductor substrate unlike a case where the gate dielectric film is entirely formed of the high-dielectric-constant material such as a metal oxide. Therefore, there is suppressed a fluctuation of a current driving force owing to a positional relationship of a boundary between a source/drain region and a channel region with respect to an edge of the gate dielectric film formed of the high-dielectric-constant material. As a result, there is realized a high-performance fine semiconductor device having a high current driving force.

Furthermore, in this field-effect transistor, isolation regions 2 are formed on the semiconductor substrate 1 by a trench isolation process. In the semiconductor substrate 1, an N-channel region 3 is formed by B ion implantation. On the N-channel region 3, the laminated gate dielectric film 10 is formed of, for example, a silicon oxide layer 11 and a hafnium dioxide layer 12. For example, polycrystal silicon having a thickness of 100 nm is deposited on the laminated gate dielectric film 10 to form a gate electrode 5. For example, a silicide layer is formed so that source/drain regions 6 are formed to sandwich the gate electrode 5 therebetween. It is to be noted that in this drawing, an interlayer dielectric film, interconnections and the like are omitted.

Next, there will be described hereinafter a method of manufacturing this field-effect transistor. First, as shown in FIG. 11, the isolation region 2 is formed on the semiconductor substrate 1 by, for example, a trench isolation process. Subsequently, for example, B ions are implanted into a P-well forming region at 100 keV and 2.0×10¹² cm⁻², and thereafter a thermal step is additionally performed at, for example, 1050° C. for 30 seconds. Subsequently, for example, B ions are implanted into a P-well region at 30 keV and 1.0×10¹² cm⁻² in order to obtain a desired threshold voltage, and a surface impurity-concentration of the N-channel region is adjusted.

Next, as shown in FIG. 12, the semiconductor substrate 1 is exposed to, for example, an oxidizing atmosphere in a temperature raised state to thereby form the silicon oxide film 11 having a thickness of, for example, 1 nm.

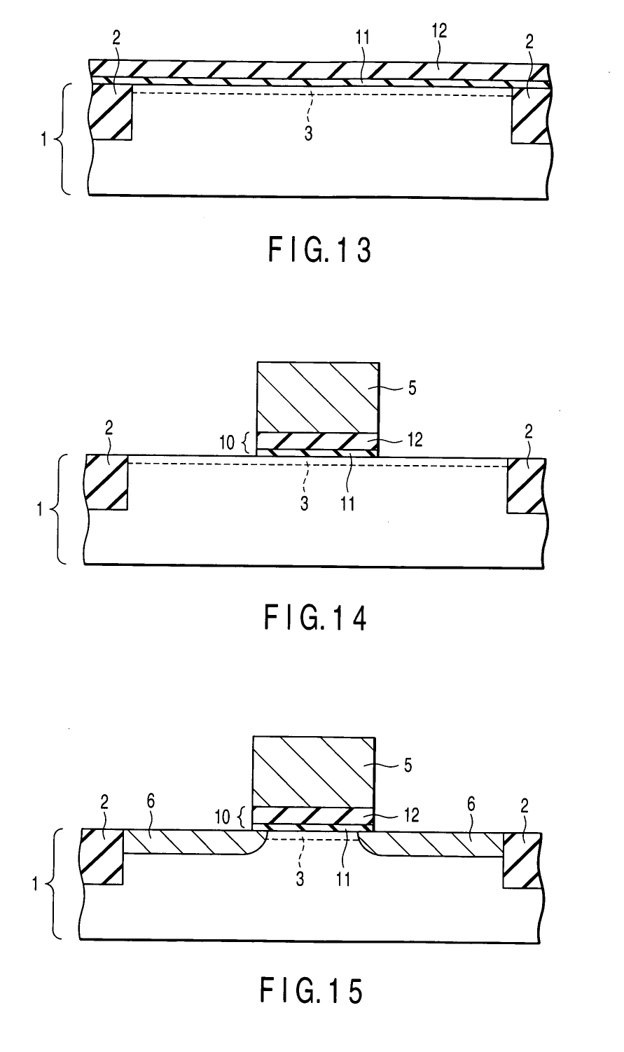

Next, as shown in FIG. 13, the hafnium dioxide (HfO₂) film 12 having a thickness of, for example, 5 nm is formed on the silicon oxide film 11 by use of a process such as chemical vapor deposition (CVD).

Next, as shown in FIG. 14, a polycrystal silicon film containing, for example, phosphor (P) and having a thickness of, for example, 100 nm is deposited on the HfO₂ film 12 by, for example, the CVD process. For example, the polycrystal silicon film is worked to form the gate electrode 5 by performing anisotropic etching such as a reactive ion etching (RIE) process. Subsequently, the HfO₂ film 12 and the silicon oxide layer 11 are worked to form the laminated gate dielectric film 10 by performing anisotropic etching such as the RIE process.

Next, as shown in FIG. 15, for example, erbium (Er) is deposited on the whole surface of the semiconductor substrate 1 by a process such as a sputtering process, and a thermal step is additionally performed to thereby form the source and drain regions 6 made of erbium and silicide on the surface of the semiconductor substrate 1. Subsequently, non-reacted erbium is removed by a process of immersing the semiconductor substrate 1 into, for example, a chemical agent.

Next, the HfO₂ film 12 is etched by the process of immersing the semiconductor substrate 1 into the chemical agent or the like, and the film is recessed inwardly from the gate electrode. Thereafter, an interlayer dielectric film forming step, an interconnection forming step and the like are performed in the same manner as in the conventional technology to form a field-effect transistor of the present invention shown in FIG. 10.

In the present embodiment, the N-type field-effect transistor has been described as an example. However, when a conductivity type of impurities is reversed, the present embodiment is applicable to a P-type field-effect transistor. Moreover, when the impurities are introduced into an only specific region of a substrate by use of a process such as the photolithography, the present embodiment is similarly applicable to a complementary field-effect transistor. The present embodiment is usable in a semiconductor device including the present embodiment as a part.

Moreover, the present embodiment is usable in forming a field-effect transistor as a part of a semiconductor device including an active element such as a bipolar transistor or a single electron transistor in addition to the field-effect transistor, a passive element such as a resistor, a diode, an inductor, or a capacitor, or an element using a ferroelectric material or a magnetic material. The present embodiment is similarly usable in forming the field-effect transistor as a part of an optoelectrical integrated circuit (OEIC) or a micro-electromechanical system (MEMS). The present embodiment is similarly used in a FIN-type element, a Π gate element, a tri-gate element, a gate all around element, or an element having a columnar structure, and a similar effect is obtained.

Furthermore, in the present embodiment, a so-called bulk element formed on a usual semiconductor device has been described as an example, but the present embodiment is similarly usable in an SOI-type element, a double-gate SOI-type element having gate electrodes on opposite side of a channel region or the like, and a similar effect is obtained.

In addition, in the present embodiment, phosphor (P) is used as impurities in forming an N-type semiconductor layer, and boron (B) is used as impurities in forming a P-type semiconductor layer, but other impurities of the group V or III may be used as the impurities in forming the N-type or P-type semiconductor layer. The impurities may be introduced in the form of a impurities-containing compound.

Moreover, in the present embodiment, the impurities are introduced into the channel region by use of ion implantation, but a process other than the ion implantation, such as solid phase diffusion or vapor phase diffusion, may be used. There may be used a process of depositing or growing an impurities-containing semiconductor. There has been used a process of depositing the impurities-containing semiconductor on the gate electrode, but a process such as the ion implantation, the solid phase diffusion, or the vapor phase diffusion may be used in introducing the impurities. When the impurities-containing semiconductor is deposited, the impurities can be introduced with a high concentration. As a result, there is an advantage that a resistance is reduced. There is an advantage that the use of the ion implantation process simplifies steps of forming a complementary element having an N-type element and a P-type element.

Moreover, in the present embodiment, Er has been used in forming a silicide layer to form the source/drain region, but another metal may be used. However, in the N-type field-effect transistor, the Fermi level of the source/drain region preferably has a value close to that of a lower end of a conduction band of a semiconductor for use in the substrate. From this viewpoint, Er is preferably used in a case where a silicon substrate is used.

Furthermore, in the P-type field-effect transistor, the Fermi level of the source/drain region preferably has a value close to that of an upper end of a valence band of a semiconductor for use in the substrate. From this viewpoint, platinum (Pt) is preferably used in a case where the silicon substrate is used. In a case where the complementary element including both of the N-type and P-type elements is formed, when using a material whose Fermi level is in the vicinity of the center of a forbidden gap of the semiconductor for use in the substrate, there is an advantage that the steps are simplified. From this viewpoint, to form the complementary element in which silicon is used in the substrate, nickel (Ni) or cobalt (Co) is preferably used.

In addition, not silicide but a metal may be used in forming the source/drain region. In this case, there is an advantage that the resistance of the source/drain region is further reduced. However, as described in the present embodiment, when the source/drain region is made of silicide, the source/drain region can be formed in a self-aligned manner with respect to the gate electrode and isolation region, and there is an advantage that the steps are simplified.

Moreover, in the present embodiment, the introduction of the impurities into the source/drain forming region has not been described, but the impurities may be introduced into the source/drain forming region. Especially when the impurities of a conductivity type opposite to that of the channel region are introduced into the source/drain forming region with a high concentration, and the Schottky barrier is formed to be thin between the source/drain region and the channel region, the resistance is preferably lowered.

Furthermore, in the present embodiment, the source/drain region is formed after working the gate electrode and the gate dielectric film, but this order is not intrinsic, and a reverse order may be used. However, in a case where the source/drain region is formed of a silicide layer as in the present embodiment, when the source/drain region is formed after working the gate electrode and the gate dielectric film, the source/drain region can be formed in the self-aligned manner with respect to the gate electrode and the isolation region, and there is an advantage that the steps are simplified.

In addition, in a case where an SOI element is formed, an impurity concentration of the channel region may be set so that a fully or partially depleted element is constituted. When the concentration is set so that the fully depleted element is formed, the impurity concentration of the channel region is reduced. Therefore, there is obtained an advantage that mobility is improved, and a current driving capability is further improved. It is preferably possible to obtain another advantage that a parasitic bipolar effect is suppressed.

Moreover, in the present embodiment, polycrystal silicon is used in the gate electrode, but the gate electrode may be formed of: a semiconductor such as single crystal silicon or amorphous silicon; a refractory metal or a metal which is not necessarily refractory; a metal-containing compound; a laminated layer of any of them or the like. When the gate electrode is made of the metal or the metal-containing compound, the gate resistance is suppressed. Therefore, a high-speed operation of the element is preferably obtained. When the gate is made of the metal, an oxidizing reaction does not easily proceed. Therefore, there is an advantage that the controllability of an interface between the gate dielectric film and the gate electrode is satisfactory. When a semiconductor such as polycrystal silicon is used in at least a part of the gate electrode, it is easy to control a work function. Therefore, there is another advantage that adjustment of the threshold voltage of the element is facilitated.

Furthermore, in the present embodiment, an upper part of the gate electrode has a structure in which the electrode is exposed, but the upper part may be provided with a dielectric material such as silicon oxide, silicon nitride, or silicon oxynitride. Especially in a case where the gate electrode is formed of a metal-containing material, when the gate electrode needs to be protected during manufacturing steps, it is important to dispose a protecting material such as silicon oxide, silicon nitride, or silicon oxynitride in the upper part of the gate electrode.

In addition, in the present embodiment, the gate electrode is formed by a process of depositing a gate electrode material and thereafter performing the anisotropic etching, but the gate electrode may be formed by use of a burying process such as a damascene process. In a case where the source/drain region is formed prior to the formation of the gate electrode, when the damascene process is used, the source/drain region and the gate electrode are preferably formed in the self-aligned manner.

Moreover, in the present embodiment, a length of the gate electrode measured along a main direction of a current flowing through the element is equal in upper and lower parts of the gate electrode, but this is not intrinsic. For example, the gate electrode may be formed into the shape of the letter T such that the measured length of the upper part of the gate electrode is large than that of the lower part. In this case, there is obtained another advantage that the gate resistance can be reduced.

Furthermore, in the present embodiment, the film of the laminated gate dielectric film close to the substrate is made of silicon oxide, but the present invention is not limited to this embodiment, and the film may be made of silicon nitride, silicon oxynitride or the like. However, when the capacitive coupling formed between the source region and the channel region is suppressed by the electric force line extending through the gate dielectric film, the current driving force is improved. Therefore, the dielectric constant of this film is preferably small. When this film is made of silicon oxide, the mobility of the carrier is improved. Therefore, there is an advantage that the current driving capability is further improved.

In addition, electric charges, interfacial states and the like existing in the dielectric film or the interface between the film and the semiconductor substrate are reduced. Therefore, from this viewpoint, silicon oxide is used in a film which comes into contact with the semiconductor substrate. On the other hand, in a case where the impurities-containing semiconductor is used in the gate electrode, from a viewpoint of preventing the impurities in the gate electrode from being diffused in the channel region, it is known that the impurities are inhibited from being diffused by the presence of nitrogen. Therefore, silicon nitride or silicon oxynitride is preferably used. A process of forming these films is possible by use of, for example, a process of exposing the films to an oxygen nitrogen gas at a raised temperature or depositing the films, and the films may be exposed to the oxygen nitrogen gas in an excited state which is not necessarily accompanied by a temperature rise. When the films are formed by the process of exposing the films to the oxygen nitrogen gas having the excited state which does not involve any temperature rise, the impurities in the channel region are preferably inhibited from being diffused to change a concentration distribution.

Furthermore, in a case where silicon oxynitride is used, first a silicon oxide film is formed, and thereafter the film may be exposed to a nitrogen-containing gas at the raised temperature or in an excited state to thereby introduce nitrogen into the dielectric film. In this case, when the films are formed by a process of exposing the films to the nitrogen gas having the excited state which does not involve any temperature rise, the impurities in the channel region are preferably inhibited from being diffused to change the concentration distribution.

In addition, in the present embodiment, an HfO₂ film is formed by the sputtering process for use as a film of the laminated gate dielectric film, which is distant from the substrate, but another dielectric film may be used which is made of: oxide such as hafnium (Hf) oxide having a different valence or oxide of another metal such as zirconium (Zr), titanium (Ti), scandium (Sc), yttrium (Y), tantalum (Ta), aluminum (Al), lanthanum (La), cerium (Ce), praseodymium (Pr), or a lanthanum series element; a silicate material containing silicon in addition to various elements including the above elements; or a material containing nitrogen in addition to the above material. Another high-dielectric-constant film or a laminated high-dielectric-constant film may be used. When the material having a high dielectric constant is used in this manner, it is possible to set the film thickness in the geometric sense to be large in order to realize a desired equivalent oxide thickness of the film. Therefore, there is obtained an advantage that the gate current is suppressed while keeping controllability of the gate electrode with respect to the potential of the channel region.

Moreover, when nitrogen exists in the dielectric film, it is preferably inhibited from that an only specific element is crystallized or precipitated. In a case where nitrogen exists in the dielectric film, when the impurities-containing semiconductor is used as the gate electrode, there is preferably another advantage that the impurities are inhibited from being diffused in the substrate.

Furthermore, the process of forming the dielectric film is not limited to the CVD process, and there may be used another process such as a vacuum evaporation process, the sputtering process, or an epitaxial growing process. When oxide of a certain substance is used in the dielectric film, a process may be used in which a film of the substance is first formed, and oxidized.

In addition, in the method of the present invention, the gate dielectric film is formed by laminating layers formed of materials having high and low dielectric constants. Unlike a case where the gate dielectric film is formed of the high-dielectric-constant material only, the film thickness of the gate dielectric film in the geometric sense is set to be small, thereby preventing the electric force line extending out of the gate from being leaked from a side surface of the gate dielectric film. Therefore, the effect of the high-dielectric-constant film is remarkable in a case where a material such as metal oxide having a sufficiently high dielectric constant is used as compared with silicon oxide for use in the gate dielectric film of the conventional device.

Moreover, in the present embodiment, the gate dielectric film is a laminated film of two layers, but three or more layers may be laminated. Furthermore, a thickness of the dielectric film or the like forming the gate dielectric film is not limited to the value of the present embodiment. In addition, it is assumed that the gate dielectric film has a uniform thickness, but this is not intrinsic.

Furthermore, in the present embodiment, a sidewall of the gate electrode is not mentioned, but the sidewall may be formed. In a case where the source/drain region is formed in the silicide layer, when the sidewall is disposed on the gate electrode, there is obtained an advantage that short-circuit between the gate electrode and the source/drain region is prevented during the formation of the silicide layer.

On the other hand, when the source/drain region is formed without disposing any sidewall as in the present embodiment, there is obtained an advantage that controllability is improved with respect to a length of the source/drain region to be drawn under the gate electrode, that is, an overlapping length between the source/drain region and the gate electrode.

In addition, in the present embodiment, the elements are isolated by use of the trench isolation process, but the elements may be isolated by use of another process such as a local oxidation process or a mesa isolation process.

Moreover, in the present embodiment, post-oxidation after the formation of the gate electrode is not mentioned. However, a post-oxidation step may be performed if possible in view of a material or the like of the gate electrode or the gate dielectric film. The present embodiment is not necessarily limited to the post-oxidation, and there may be performed a step of rounding corners of lower ends of the gate electrode by a process such as a chemical agent treatment or exposure to a reactive gas. If the step is possible, an electric field of each gate electrode lower-end corner is preferably relieved.

Furthermore, in the present embodiment, the interlayer dielectric film is not mentioned, but a substance other than silicon oxide, such as a low-dielectric-constant, may be used in the interlayer dielectric film. When a dielectric constant of the interlayer dielectric film is lowered, a parasitic capacitance of the element is reduced, and therefore there is an advantage that the high-speed operation of the element can be achieved.

In addition, a contact hole is not mentioned, but a self-aligned contact may be formed. Since the use of the self-aligned contact can reduce an area of the element, a degree of integration is preferably improved.

Moreover, in the present embodiment, formation of a metal layer for interconnections is not mentioned, but a metal such as copper (Cu) may be used in the layer. Especially, Cu is preferable because it has a small resistivity.

It is to be noted that the structure of the single transistor only has been described in the present embodiment, but the embodiment described herein is not limited to the single transistor, and needless to say, the similar effect is obtained.

(Second Embodiment)

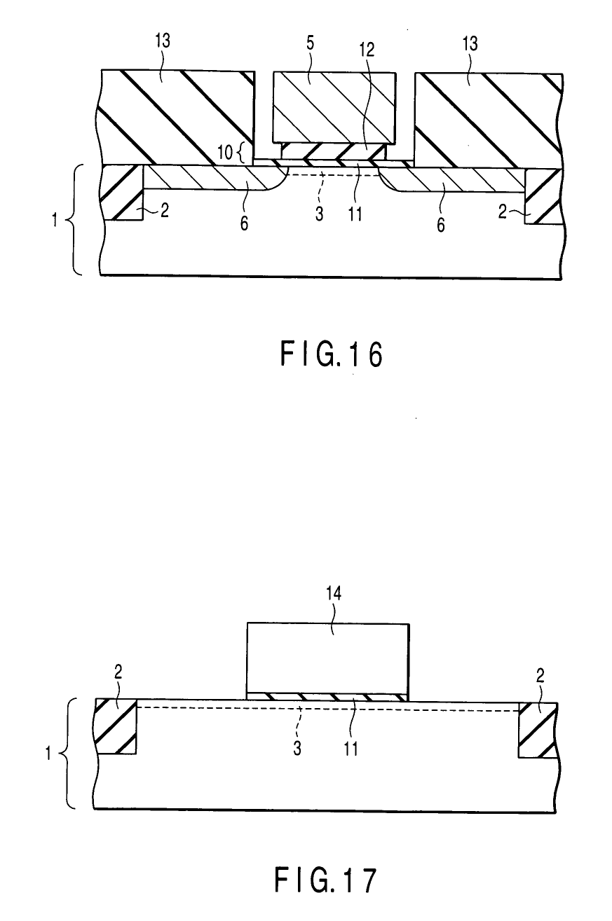

FIG. 16 is a sectional view of a semiconductor device in a second embodiment of the present invention. This field-effect transistor is a Schottky-type field-effect transistor, and a gate dielectric film 10 is formed of laminated layers including a film 11 made of silicon oxide and a film 12 made of a high-dielectric-constant material such as metal oxide. This gate dielectric film 10 has characteristics that the film 12 formed of the high-dielectric-constant material such as metal oxide is formed to be shorter than a gate electrode, opposing edges of the gate dielectric film and a source/drain region 6 are aligned or overlap with each other, and the film 11 made of silicon oxide is formed to be longer than the film 12 formed of the high-dielectric-constant material and to cover the opposing edges of the source/drain regions 6.

Moreover, in this field-effect transistor, isolation regions 2 are formed on the semiconductor substrate 1 by, for example, a trench isolation process. In the semiconductor substrate 1, an N-channel region 3 is formed by, for example, B-ion implantation. On the N-channel region 3, the laminated gate dielectric film 10 is formed of, for example, the silicon oxide film 11 and the hafnium dioxide film 12. For example, a refractory metal such as tungsten (W) having a thickness of 100 nm is deposited on the laminated gate dielectric film 10 to form a gate electrode 5.

Furthermore, for example, a silicide layer is formed so that source/drain regions 6 are formed to sandwich the gate electrode 5 therebetween. Moreover, an silicon oxide film 13 is formed to cover the source/drain regions 6. It is to be noted that in this drawing, an interlayer dielectric film, interconnections and the like are omitted.

Next, there will be described a method of manufacturing this field-effect transistor. Subsequently to the step shown in FIG. 12 in the first embodiment, as shown in FIG. 17, for example, a polycrystal silicon film having a thickness of 100 nm is deposited on the silicon oxide film 11 by, for example, a CVD process, and the film is worked by a process such as an RIE process to form a dummy gate electrode 14. Subsequently, the silicon oxide film 11 is worked.

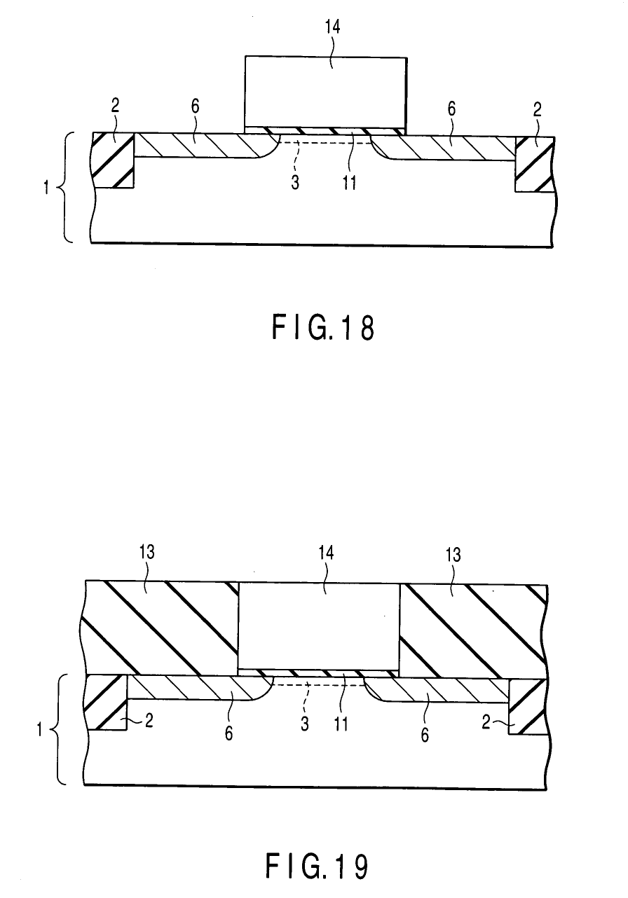

Next, as shown in FIG. 18, for example, Er is deposited on the whole surface of a semiconductor substrate 1 by a process such as the sputtering process, and a thermal step is additionally performed to thereby form the source/drain regions 6 made of erbium and silicide on the surface of the semiconductor substrate 1. Subsequently, non-reacted erbium is removed by, for example, a process of immerging the semiconductor substrate 1 in a chemical agent.

Next, as shown in FIG. 19, for example, the silicon oxide film 13 is formed on the whole surface of the semiconductor substrate by a process such as a CVD process. Subsequently, the surface is flattened by a process such as a chemical mechanical polishing (CMP) process to expose a top of the dummy gate electrode 14.

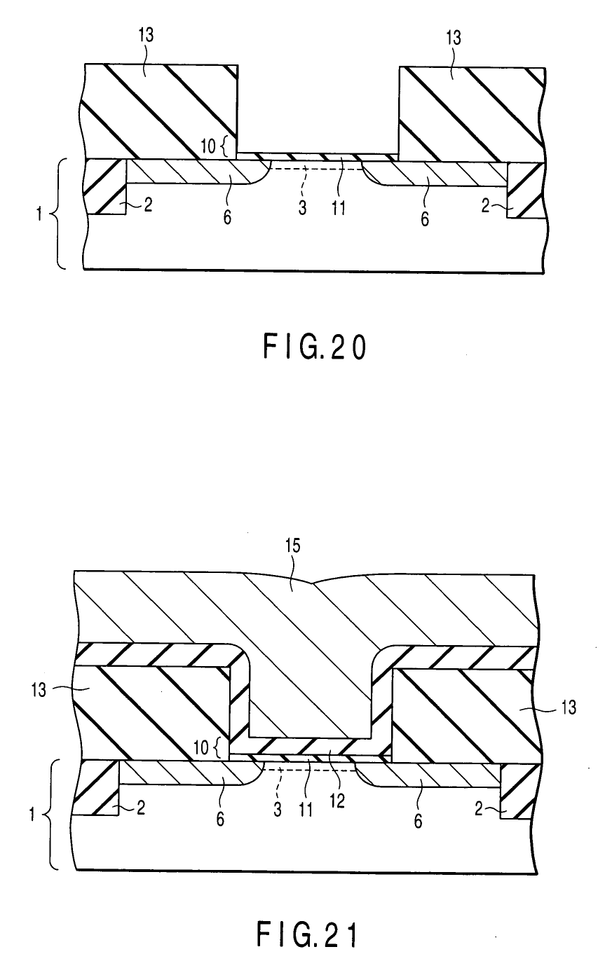

Next, as shown in FIG. 20, the dummy gate electrode 14 is removed by a process such as a chemical dry etching (CDE) process.

Next, as shown in FIG. 21, the HfO₂ film 12 having a thickness of, for example, 5 nm is formed by use of a process of the CVD process. Subsequently, a tungsten film 15 having a thickness of, for example, 100 nm is formed by use of a process such as the CVD process.

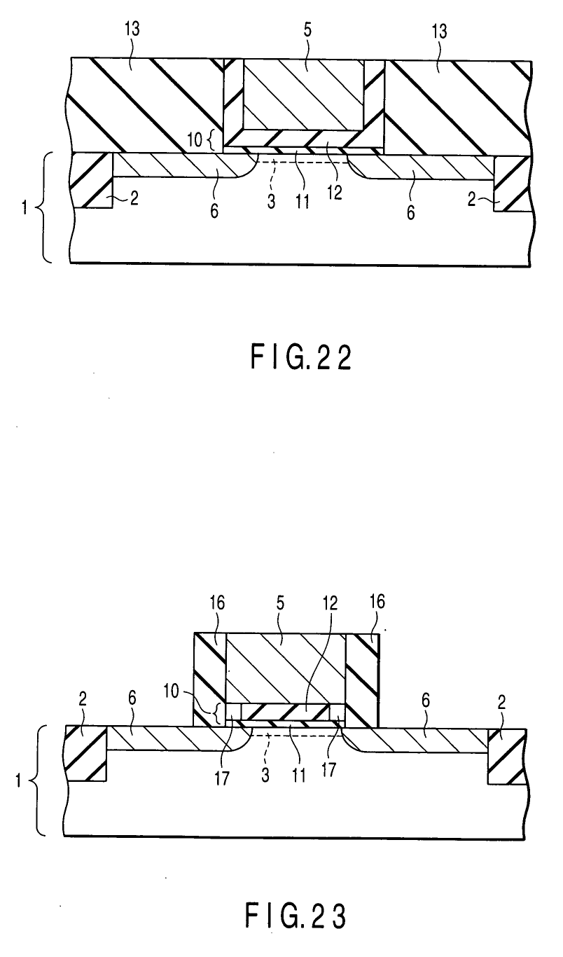

Next, as shown in FIG. 22, the surfaces of the tungsten film 15 and the HfO₂ film 12 are flattened by use of a process such as the CMP process, and the gate electrode 5 is formed.

Next, the HfO₂ film 12 is etched by a process of immerging the semiconductor substrate 1 into a chemical agent, and the film is recessed inwardly from the gate electrode. Thereafter, an field-effect transistor of the present invention shown in FIG. 16 is completed through an interlayer dielectric film forming step or an interconnection step in the same manner as in the conventional technology.

Unlike the forming method of the first embodiment, in the method of the present embodiment, the source/drain region formed beforehand is covered with the dielectric film in a step of working the high-dielectric-constant layer of the gate dielectric film. Therefore, the method has an advantage that damage to the source/drain region are reduced in the step.

In the present embodiment, the formation of the interlayer dielectric film is not mentioned, but the silicon oxide film 13 may be used in a part of the interlayer dielectric film. Moreover, in the present embodiment, the silicon oxide film formed on the semiconductor substrate surface prior to the formation of the dummy gate electrode is used in a part of the gate dielectric film, but subsequently to removal of the dummy gate electrode, this film may be removed, and a low-dielectric-constant layer may be newly formed in the gate dielectric film. When the layer is newly formed in this manner, there is an advantage that it is possible to use, in the gate dielectric film, an dielectric film that is not damaged by the step of removing the dummy gate electrode.

On the other hand, when the dielectric film formed on the semiconductor substrate surface prior to the formation of the dummy gate electrode is used in a part of the gate dielectric film as described in the present embodiment, there is an advantage that the steps are simplified. In addition, there is an advantage that it is possible to reduce the damage to the source/drain region in the step after the region is formed.

Moreover, in the present embodiment, after forming the dielectric film on the semiconductor substrate surface and forming the dummy gate electrode, silicon oxide is used as the dielectric film to be formed on the source/drain region, but this is not intrinsic, and another material such as silicon nitride may be used. When silicon nitride is used and a material that is not corroded by hydrofluoric acid is used as a gate electrode material, alternatively, the gate electrode material is covered with the material that is not corroded by hydrofluoric acid, there is obtained an advantage that it is possible to use hydrofluoric acid which has heretofore been used often in a conventional method of manufacturing a semiconductor device and whose property is well known in the step of removing the high-dielectric-constant layer from the gate dielectric film.

Even in the present embodiment, various modifications described in the first embodiment are possible, and a similar effect is obtained.

(Third Embodiment)

FIG. 23 is a sectional view of a semiconductor device in a third embodiment of the present invention. This field-effect transistor is a Schottky-type field-effect transistor, and a gate dielectric film 10 is formed of laminated layers including a film 11 made of silicon oxide and a film 12 made of a high-dielectric-constant material such as metal oxide. Furthermore, this transistor has characteristics that the film 12 formed of the high-dielectric-constant material such as metal oxide is formed to be shorter than a gate electrode, gate sidewalls 16 are disposed, and gaps 17 are defined by the gate sidewalls 16, a gate electrode 5, and the gate dielectric film 10.

When the transistor is constituted as described above, the gap is disposed in each region where the gate electrode overlaps with the source/drain region, and therefore a parasitic capacitance of an element is reduced. As a result, there is an advantage that a large current driving force is obtained, a load capacitance is reduced, and a higher-speed operation is realized. It is to be noted that even in the present embodiment, opposing edges of a film 12 formed of a high-dielectric-constant material and source/drain regions 6 are aligned or overlap with each other. It is to be noted that in this drawing, an interlayer dielectric film, interconnections and the like are omitted.

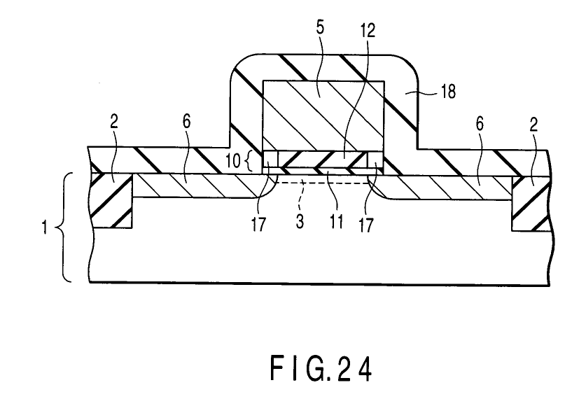

Next, there will be described a method of manufacturing this field-effect transistor. Subsequently to the step shown in FIG. 15 in the first embodiment, as shown in FIG. 24, the HfO₂ film 12 is etched by a process of immersing a semiconductor substrate 1 into a chemical agent, and the film is recessed inwardly from the gate electrode 5. Subsequently, for example, an silicon oxide film 18 is deposited on the whole surface of the semiconductor substrate by a process such as CVD. At this time, deposition conditions are adjusted so that the gaps 17 are generated under edges of the gate electrode.

Subsequently, the silicon oxide film 18 is worked to form the gate sidewalls 16 by use of a process such as an RIE process. Thereafter, the field-effect transistor of the present invention shown in FIG. 23 is completed through an interlayer dielectric film forming step or an interconnection step in the same manner as in the conventional technology.

In the present embodiment, the gate sidewalls 16 are disposed, and the gaps 17 are defined by the gate sidewalls 16, the gate electrode 5, and the gate dielectric film 10. Since the gaps are disposed in this manner in each region where the gate electrode overlaps with the source/drain region, the parasitic capacitance of the element is reduced. As a result, there is an advantage that a high current driving force is obtained. Moreover, a load capacitance is reduced to realize a higher-speed operation.

In the present embodiment, the low-dielectric-constant layer of the laminated gate dielectric film close to the semiconductor substrate is worked to be aligned with the gate electrode, but this is not intrinsic, and this layer may be recessed from the gate edges. In this case, the gap 17 is surrounded by the gate sidewall 16, the gate electrode 5, the gate dielectric film 10, and the semiconductor substrate 1.

However, if the low-dielectric-constant layer of the laminated gate dielectric film close to the semiconductor substrate is not recessed from the gate electrode, the source/drain region formed beforehand is covered with the dielectric film in a step of working a high-dielectric-constant layer of the gate dielectric film. Therefore, there is an advantage that damage to the source/drain region are reduced in the step.

Even in the present embodiment, various modifications described in the first embodiment are possible, and a similar effect is obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor layer;
a pair of a source region and a drain region formed to face each other in a direction on the semiconductor layer and made of a metal or a metal silicide;
a first dielectric film formed on at least the semiconductor layer between the source region and the drain region;
a second dielectric film formed on the first dielectric film and having a dielectric constant higher than that of the first dielectric film; and
a gate electrode formed on the second dielectric film,
a length of the second dielectric film measured in the direction being shorter than that of the gate electrode measured in the direction.

2. The semiconductor device according to claim 1, wherein the length of the first dielectric film measured in the direction is longer than that of the second dielectric film measured in the direction.

3. The semiconductor device according to claim 1, wherein the first dielectric film includes a silicon oxide film, and the second dielectric film includes a metal.

4. The semiconductor device according to claim 3, wherein a thickness of the first dielectric film is 0.2 nm or more, and is smaller than an equivalent oxide thickness of the second dielectric film.

5. The semiconductor device according to claim 1, wherein the first dielectric film includes a silicon nitride film, and the second dielectric film includes a metal.

6. The semiconductor device according to claim 5, wherein an equivalent oxide thickness of the first dielectric film is 0.2 nm or more, and is smaller than that of the second dielectric film.

7. A semiconductor device comprising:
a semiconductor layer;
a pair of a source region and a drain region formed to face each other in a direction on the semiconductor layer and made of a metal or a metal silicide;
a first dielectric film formed on at least the semiconductor layer between the source region and the drain region;
a second dielectric film formed on the first dielectric film and having a dielectric constant higher than that of the first dielectric film; and
a gate electrode formed on the second dielectric film,
a length of the second dielectric film measured in the direction being shorter than that of the gate electrode measured in the direction, and the second dielectric film having a region whose opposing edges are aligned or overlap with the source region and the drain region.

8. The semiconductor device according to claim 7, wherein the length of the first dielectric film measured in the direction is longer than that of the second dielectric film measured in the direction.

9. The semiconductor device according to claim 7, wherein the first dielectric film includes a silicon oxide film, and the second dielectric film includes a metal.

10. The semiconductor device according to claim 9, wherein a thickness of the first dielectric film is 0.2 nm or more, and is smaller than an equivalent oxide thickness of the second dielectric film.

11. The semiconductor device according to claim 7, wherein the first dielectric film includes a silicon nitride film, and the second dielectric film includes a metal.

12. The semiconductor device according to claim 11, wherein an equivalent oxide thickness of the first dielectric film is 0.2 nm or more, and is smaller than that of the second dielectric film.

13. A semiconductor device comprising:
a semiconductor layer;
a pair of a source region and a drain region formed to face each other in a direction on the semiconductor layer and made of a metal or a metal silicide;
a first dielectric film formed on at least the semiconductor layer between the source region and the drain region;
a second dielectric film formed on the first dielectric film and having a dielectric constant higher than that of the first dielectric film; and
a gate electrode formed on the second dielectric film,
a length of the second dielectric film measured in the direction being shorter than that of the gate electrode measured in the direction, the gate electrode having a region which overlaps with at least a part of the source region and the drain region, and the overlapping region having a void.

14. The semiconductor device according to claim 13, wherein the length of the first dielectric film measured in the direction is longer than that of the second dielectric film measured in the direction.

15. The semiconductor device according to claim 13, wherein the first dielectric film includes a silicon oxide film, and the second dielectric film includes a metal.

16. The semiconductor device according to claim 15, wherein a thickness of the first dielectric film is 0.2 nm or more, and is smaller than an equivalent oxide thickness of the second dielectric film.

17. The semiconductor device according to claim 13, wherein the first dielectric film includes a silicon nitride film, and the second dielectric film includes a metal.

18. The semiconductor device according to claim 17, wherein an equivalent oxide thickness of the first dielectric film is 0.2 nm or more, and is smaller than that of the second dielectric film.
